(19) United States
(12) Patent Application Publication
(10) Pub. No.: US 2023/0280427 A1
(43) Pub. Date: Sep. 7, 2023

(54) SPATIAL ENCODING ARRANGEMENT

(71) Applicant: THE UNIVERSITY OF QUEENSLAND, St Lucia, Queensland (AU)

(72) Inventors: Michael Werner VOGEL, St Lucia, Queensland (AU); Ruben Pellicer GURIDI, St Lucia, Queensland (AU); Viktor VEGH, St Lucia, Queensland (AU); David Charles REUTENS, St Lucia, Queensland (AU)

(21) Appl. No.: 18/017,266

(22) PCT Filed: Jul. 22, 2021
(86) PCT No.: PCT/AU2021/050787

§ 371 Date: Jan. 20, 2023

(30) Foreign Application Priority Data
Jul. 22, 2020 (AU) 2020902536

(51) Int. Cl. G01R 33/44; G01R 33/383

(52) U.S. Cl. CPC G01R 33/445; G01R 33/383

(57) ABSTRACT

A spatial encoding arrangement forming part of a low field magnetic resonance imaging system for generating a spatially encoded measurement field for use in a low field magnetic resonance imaging process, the low field magnetic resonance imaging system including a pre-polarisation magnet arrangement for generating a pre-polarisation field in a field-of-view and a measurement magnet arrangement for generating a measurement field in the field-of-view, the spatial encoding arrangement including at least one magnetic encoding element movable relative to the field-of-view to thereby spatially encode the measurement field for each of a plurality of readings.

### BACKGROUND OF THE INVENTION

The present invention relates to a spatial encoding arrangement for use in a low field magnetic resonance process.

### DESCRIPTION OF THE PRIOR ART

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

Nuclear magnetic resonance (NMR) spectroscopy and magnetic resonance imaging (MRI) are non-invasive and non-destructive investigative tools that can provide information from the molecular to the macroscopic scale. These techniques harness the phenomenon of magnetic resonance due to the interaction, within a magnetic field, between precessing nuclear magnetic moments (nuclear spin systems) and electromagnetic fields. NMR/MRI have a wide range of applications in materials science, structural biology, chemistry and medical imaging.

Conventional MRI instruments comprise three main components: a superconducting magnet to align the nuclear spins and generate net sample magnetisation; a transmitter/receiver coil system that radiates electromagnetic energy to the nuclear spin system and detects the NMR signal; and gradient coils that enable the encoding of spatial information allowing the generation of three dimensional images.

The signal-to-noise ratio (SNR) achieved by an NMR/MRI system is proportional to the magnitude of net sample magnetisation. Hence, the quality of NMR/MRI data is dependent on the field strength of the main magnetic field, commonly referred to as the reference field and denoted as Bo. Additionally, as well as field strength, the homogeneity of the Bo field is important in ensuring the quality of the resulting data. Superconducting magnets have been utilised to achieve high field strength. These increase the bulk and cost of purchase, operation and maintenance of NMR/MRI instruments because of cryogenic technology required.

Partly in response to these drawbacks, over the last decade there has been growing interest in low magnetic field, which uses a main magnet field strength of less than 0.5 T. Potential advantages of low field over high field NMR/MRI instruments include greater absolute magnetic field homogeneity, simple and low cost instrumentation and low power consumption. Low field NMR/MRI offers the possibility of important new applications such as the ability to image in the presence of metal, for example in trauma, disaster and battlefield applications. At low field, the Larmor frequency overlaps with a range of molecular and physiological processes such as protein folding, slow diffusion, molecular tumbling and enzyme catalysis which are difficult to observe at high field because of the large frequency mismatch. This raises the possibility of new imaging paradigms sensitised to these processes. In addition, because superconducting magnets are not required, the instruments may be more portable, allowing low field instruments to be used in remote locations.

Although based on the same fundamental principles of magnetic resonance as high field NMR/MRI, low field instruments are set up differently. Prior to the measurement, sample magnetisation is generated by a pulsed magnetic field. This technique is known as sample pre-polarisation and is a key strategy in low field research to overcome low SNR which still severely restricts low field NMR/MRI applications. Highly sensitive magnetometers are also used to increase SNR. The low field NMR/MRI signal is detected in the presence of a second magnetic field, the measurement field, which is perpendicular to the pre-polarisation field.

The magnetic fields in most low field NMR/MRI instruments are generated using resistive coils, which have high power consumption and heat production, caused by irreversible energy dissipation. Moreover, the presence of highly conductive materials in resistive coils contributes to signal loss due to sample heating effects, residual coil noise, transients and eddy currents, and destructive interference effects.

The concept of a dynamic adjustable permanent magnet array (SPMA) exploiting the advantages of Halbach arrays to generate and control multiple magnetic fields is described in Vogel M W, Giorni A, Vegh V, Reutens D C. “Ultra-low field nuclear magnetic resonance relaxometry with a small permanent magnet array: A design study.” PLoS One. 2016; 11(6). However, for low field imaging instruments, no permanent magnet based gradient devices have been developed due to the difficulties in generating multiple linear encoding fields with varying magnitudes and directions required for using standard methods like fast Fourier transform (FFT) for image reconstruction. Moreover, the presence of prominent concomitant fields, which result in image distortions, needs to be corrected during image reconstruction.

### SUMMARY OF THE PRESENT INVENTION

In one broad form, an aspect of the present invention seeks to provide a spatial encoding arrangement forming part of a low field magnetic resonance imaging system for generating a spatially encoded measurement field for use in a low field magnetic resonance imaging process, the low field magnetic resonance imaging system including a pre-polarisation magnet arrangement for generating a pre-polarisation field in a field-of-view and a measurement magnet arrangement for generating a measurement field in the field-of-view, the spatial encoding arrangement including at least one magnetic encoding element movable relative to the field-of-view to thereby spatially encode the measurement field for each of a plurality of readings.

In one embodiment the at least one magnetic encoding element includes at least one of: at least one permanent encoding magnet; and, at least one ferromagnetic encoding element.

In one embodiment the at least one encoding element is moved at least one of: circumferentially around the field-of-view; axially in a direction parallel to a field-of-view axis; along a spiral trajectory around and along a field-of-view axis; and, axially at least one of: linearly; non-linearly; and, quadratically.

In one embodiment the at least one magnetic encoding element is mounted on an annular support extending around the field-of-view with a support axis coincident with the field-of-view axis.

In one embodiment the annular support is rotated and moved axially relative to the field-of-view.

In one embodiment the spatial encoding arrangement includes an actuator for moving at least one magnetic encoding element.

In one embodiment the apparatus includes one or more electronic processing devices that cause the at least one magnetic encoding element to move between successive measurements.

In one embodiment the at least one magnetic encoding element includes first and second magnetic encoding elements and wherein: the first magnetic encoding element is at least one of static and movable relative to the measurement field; and, the second magnetic encoding element is movable relative to the measurement field.

In one embodiment the at least one magnetic encoding element includes an array including a plurality of permanent encoding magnets.

In one embodiment the plurality of permanent encoding magnets are circumferentially spaced about the field-of-view.

In one embodiment the encoding magnets are at least one of: circumferentially spaced about a common axial position; and, axially spaced.

In one embodiment the plurality of encoding magnets includes at least two permanent encoding magnets having at least one of: different orientations relative to a field-of-view axis; and, different radial spacings from the field-of-view axis.

In one embodiment the plurality of encoding magnets includes at least one of: at least one encoding magnet orientated with a magnetisation direction extending perpendicularly to a field-of-view axis; and, at least one encoding magnet orientated with a magnetisation direction extending parallel with the field-of-view axis.

In one embodiment the plurality of encoding magnets includes: a first encoding magnet orientated with a magnetisation direction extending radially outwardly from the field-of-view axis; and, a second encoding magnet orientated with a magnetisation direction extending radially outwardly from the field-of-view axis, and wherein the first and second encoding magnets are moved along respective spiral trajectories.

In one embodiment the plurality of encoding magnets includes two encoding magnets having a first radial spacing from a field-of-view axis and two encoding magnets having a second radial spacing.

In one embodiment the at least one magnetic encoding element includes an array of permanent encoding magnets that generate a predetermined spatial encoding field.

In one embodiment the predetermined spatial encoding field is a gradient field and the array of permanent encoding magnets is a modified Halbach array.

In one embodiment the spatial encoding arrangement includes: at least one magnetic encoding element mounted to a first support; and, at least one magnetic encoding element mounted to a second support, at least one of the first and second supports being movable relative to the measurement encoding magnet arrangement.

In one broad form, an aspect of the present invention seeks to provide a magnet system for use in a low field magnetic resonance imaging process, the system including: a pre-polarisation magnet arrangement for generating a pre-polarisation field in a field-of-view; a measurement magnet arrangement for generating a measurement field in the field-of-view; a spatial encoding arrangement including at least one magnetic encoding element movable relative to the field-of-view to thereby spatially encode the measurement field for each of a plurality of readings.

In one embodiment the at least one magnetic encoding element is provided at least one of: radially inwardly of the pre-polarisation magnet arrangement; radially outwardly of the pre-polarisation magnet arrangement; radially outwardly of the measurement magnet arrangement; radially inwardly of the measurement magnet arrangement; and, between the pre-polarisation magnet arrangement and the measurement magnet arrangement.

In one embodiment: the pre-polarisation magnet arrangement generates a pre-polarisation field having a pre-polarisation field direction perpendicular to the array axis; and, the measurement magnet arrangement generates a measurement field having a measurement field direction perpendicular to the array axis and the pre-polarisation field direction.

In one embodiment the measurement magnet arrangement includes: a first measurement array including a plurality of permanent first measurement magnets mounted in a first support in a circumferentially spaced arrangement and configured to generate a first field in a field-of-view, the first field being orientated in a first direction relative to the first support; and a second measurement array including a plurality of permanent second measurement magnets mounted in a second support in a circumferentially spaced arrangement and configured to generate a second field in the field-of-view, the second field being orientated in a second direction relative to the second support, wherein the first and second supports are concentrically arranged about a field-of-view so that first and second measurement arrays can be rotated relatively allowing a strength of a measurement field in the field-of-view to be controlled.

In one embodiment: when the first and second directions are in opposition a measurement field in the field-of-view is minimised; and, when the first and second directions are at least partially aligned with a measurement field direction, a net measurement field is generated extending in the measurement field direction, with the strength of the measurement field being controlled by a degree of alignment of the first and second directions.

In one embodiment the first and second measurement arrays are configured as respective cylindrical Halbach arrays.

In one embodiment the measurement magnet arrangement includes mechanical coupling between the first and second measurement arrays so that the first and second measurement arrays are rotated synchronously in opposing directions.

In one embodiment the measurement magnet arrangement includes a measurement actuator system for relatively rotating the first and second permanent magnet arrays.

In one embodiment the measurement actuator system includes a drive member and a mechanical linkage coupling that rotates at least one of the first and second supports.

In one embodiment the mechanical linkage includes one or more gears and the drive member includes a gear wheel.

In one embodiment the measurement actuator system is at least one of coupled to and part of a pre-polarisation actuator system for rotating pre-polarisation magnets in a pre-polarisation array between the first and second positions to thereby control a pre-polarisation field.

In one embodiment the measurement actuator system is at least one of: pneumatically operated; hydraulically operated; manually operated; and, electrically operated using a motor.

In one embodiment the first and second supports include respective annular cylindrical support bodies having support body axes coincident with a field-of-view axis and wherein the measurement field direction is perpendicular to a pre-polarisation field direction and the field-of-view axis.

In one embodiment the measurement magnets are elongated bar magnets extending parallel to a field-of-view axis of the field-of-view and with poles orientated perpendicularly to the field-of-view axis.

In one embodiment the measurement field has at least one of: a strength adjustable between 0 μT and 0.01 T; a field homogeneity of at least one of: greater than 200 ppm; and, greater than 230 ppm.

In one embodiment the pre-polarising magnet arrangement including a pre-polarisation field array including a plurality of permanent pre-polarisation magnets mounted in a support and provided in a circumferentially spaced arrangement surrounding the field-of-view, a number of the pre-polarisation magnets being rotatable between respective first and second positions, wherein: in the first position the pre-polarisation magnets are configured as a cylindrical Halbach array to generate a pre-polarisation field in the field-of-view; and, in the second position the pre-polarisation magnets are configured to minimise a field in the field-of-view.

In one embodiment in the second position the pre-polarisation magnets are arranged at least one of: in a reverse cylindrical Halbach array; tangentially; and, radially.

In one embodiment at least some of the pre-polarisation magnets are mounted rotatably to the support allowing the pre-polarisation magnets to rotate about magnet axes parallel to an array axis.

In one embodiment the magnet arrangement includes a pre-polarisation actuator system for rotating the pre-polarisation magnets between the first and second positions to thereby control the pre-polarisation field.

In one embodiment the pre-polarisation magnets are mounted in a sleeve, mounted rotatably to the support, and wherein the actuator system engages an arm extending laterally from the sleeve.

In one embodiment the arm is coupled to a piston mounted to the support so that activation of the piston causes rotation of the magnet.

In one embodiment the pre-polarisation actuator system includes mechanical coupling between the pre-polarisation magnets so that the pre-polarisation magnets are moved in synchronisation.

In one embodiment the pre-polarisation actuator system includes a drive member and a mechanical linkage coupling each of the number of pre-polarisation magnets and the drive, so that each of the number of pre-polarisation magnets is rotated by a defined amount in a respective direction upon actuation of the drive.

In one embodiment the mechanical linkage includes one or more gears.

In one embodiment the drive member includes at least one of: a gear wheel; and, a rotary actuator.

In one embodiment the pre-polarisation actuator system is at least one of: pneumatically operated; hydraulically operated; manually operated; and, electrically operated using a motor to move the magnets between prescribed positions.

In one embodiment the pre-polarisation actuator system is configured to move the pre-polarisation magnets between first and second positions at least in part using magnetic forces between the pre-polarisation magnets.

In one embodiment the pre-polarisation actuator system includes a locking system for locking the pre-polarisation magnets in the first position.

In one embodiment the actuator system has a tolerance of less than 40 arcsecond.

In one embodiment the pre-polarisation magnets are elongated permanent bar magnets extending parallel to an array axis with a remanent magnetisation orientated perpendicularly to the array axis.

In one embodiment the support is a cylindrical support body having a support body axis coincident with the array axis and wherein the pre-polarisation field extends in a pre-polarisation field direction perpendicular to the array axis.

In one embodiment with the pre-polarisation magnets in the first position the pre-polarisation field has at least one of: a strength in the field-of-view of at least one of: at least 10 mT; at least 50 mT; and, at least 100 mT; a field inhomogeneity of at least one of: less than 230 ppm; and, less than 200 ppm.

In one embodiment in the second position the pre-polarisation field has a strength in the field-of-view of at least one of: less than 1 nT; less than 0.1 nT; and, less than 0.01 nT.

In one embodiment the field-of-view has a volume of at least one of: at least 50 cm³; at least 75 cm³; at least 100 cm³; and at least 125 cm³.

In one embodiment the apparatus includes one or more electronic processing devices that: controls the polarisation magnet arrangement to thereby generate a pre-polarisation field in the field-of-view to thereby polarise a sample; controls a position of the at least one magnetic encoding element relative to the field-of-view to thereby control a spatial encoding of the measurement field; and, acquires a reading from at least one sensor with the at least one magnetic encoding element in a first position.

In one embodiment the one or more electronic processing devices acquires multiple readings between each polarisation of the sample, the at least one magnetic encoding element being in a respective position for each of the multiple readings.

It will be appreciated that the broad forms of the invention and their respective features can be used in conjunction, interchangeably and/or independently, and reference to separate broad forms is not intended to be limiting.

### BRIEF DESCRIPTION OF THE DRAWINGS

Various examples and embodiments of the present invention will now be described with reference to the accompanying drawings, in which:—

FIG. 1A is a schematic end view of a magnet system including an example of a spatial encoding arrangement;

FIG. 1B is a schematic side view of the magnet system of FIG. 1A;

FIG. 1C is a schematic end view of the magnet system of FIG. 1A after movement of the encoding element;

FIG. 1D is a schematic side view of magnet system of FIG. 1A after movement of the encoding element;

FIG. 2A is a schematic end view of a magnet system including a second example of a spatial encoding arrangement;

FIG. 2B is a schematic side view of the magnet system of FIG. 2A;

FIG. 2C is a schematic end view of a magnet system including a third example of a spatial encoding arrangement;

FIG. 2D is a schematic side view of the magnet system of FIG. 2C;

FIG. 3A is a schematic end view of a fourth example of a spatial encoding arrangement;

FIG. 3B is a schematic side view of the spatial encoding arrangement of FIG. 3A;

FIG. 3C is a schematic end view of the spatial encoding arrangement of FIG. 3A after movement of the encoding array;

FIG. 3D is a schematic side view of the spatial encoding arrangement of FIG. 3A after movement of the encoding array;

FIG. 4A is a schematic end view of an example of a first measurement array;

FIG. 4B is a schematic end view of an example of a second measurement array;

FIG. 4C is a schematic end view of an example of a measurement magnet system with first and second measurement arrays in a first relative orientation to minimise a measurement field;

FIG. 4D is a schematic end view of the measurement magnet system of FIG. 4C with the first and second measurement arrays in a second relative orientation to generate a net measurement field;

FIG. 5A is a schematic end view of a pre-polarisation magnet array with pre-polarisation magnets in a first position to generate a pre-polarisation field;

FIG. 5B is a schematic end view of a pre-polarisation magnet array with pre-polarisation magnets in a second position to minimise the pre-polarisation field;

FIG. 6A is a schematic diagram of an example of a magnetic field generated by a pre-polarisation magnet array with pre-polarisation magnets in a first position defining a cylindrical Halbach array for generating a pre-polarisation field;

FIG. 6B is a schematic diagram of an example of a magnetic field generated by a pre-polarisation magnet array with pre-polarisation magnets in a second position defining a reverse cylindrical Halbach array for minimising the pre-polarisation field;

FIG. 6C is a schematic diagram of an example of a magnetic field generated by a pre-polarisation magnet array with pre-polarisation magnets in a tangential second position for minimising the pre-polarisation field;

FIG. 6D is a schematic diagram of an example of a magnetic field generated by a pre-polarisation magnet array with pre-polarisation magnets in a radial second position for minimising the pre-polarisation field;

FIG. 7 is a schematic end view of a first example of a magnet arrangement for generating pre-polarisation and spatially encoded measurement fields;

FIG. 8 is a schematic end view of a second example of a magnet arrangement for generating pre-polarisation and spatially encoded measurement fields;

FIGS. 9A to 9D are graphs of a typical measurement pulse sequence including a pre-polarisation field, measurement field, encoding field and sample response respectively;

FIGS. 10A to 10C and FIGS. 10D to 10F are graphs illustrating the difference between non-adiabatic and adiabatic switching of the pre-polarisation field, respectively;

FIG. 11 is a schematic diagram illustrating a basic model for encoding field calculation;

FIG. 12A is a schematic transverse view of an encoding array including two encoding magnets;

FIG. 12B is a schematic perspective diagram illustrating an azimuthal angle φ, polar angle θ and height Z(α) for part of a cylindrical support of an encoding magnet array;

FIG. 13A is a schematic diagram illustrating spiralling encoding magnet trajectories;

FIG. 13B is a graph showing movement profiles for different spiralling encoding magnet trajectories;

FIG. 14A to 14C are images illustrating the impact of axial movement of the encoding array on imaging;

FIG. 14D to 14F are negatives of the images of FIGS. 14A to 14C;

FIG. 15A is a graph showing a minimum condition number against intermediate angle;

FIG. 15B is a graph showing a minimum condition number against final angle;

FIG. 16A is a schematic diagram of an example sample structure;

FIG. 16B is a graph illustrating the convergence of image reconstruction for the sample structure of FIG. 16A;

FIG. 17A is a graph illustrating three example encoding magnet trajectories;

FIGS. 17B to 17D are representations of the reconstruction of a sample for the encoding magnet trajectories of FIG. 17A;

FIGS. 18A and 18B are schematic diagrams of first and second example encoding magnet configurations; and,

FIGS. 18C to 18H are schematic representations of sample reconstructions for the first and second example encoding magnet configurations.

### DETAILED DESCRIPTION OF THE PREFERRED EMBODIMENTS

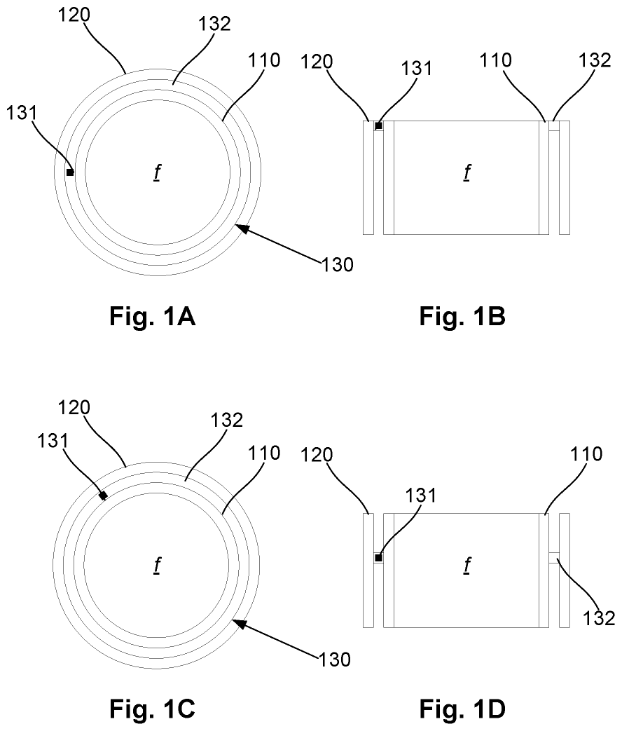

An example of a magnet system forming part of a low field magnetic resonance imaging system for generating a spatially encoded measurement field for use in a low field magnetic resonance imaging process will now be described with reference to FIGS. 1A to 1D.

In this example, the magnet system 100 includes a pre-polarisation magnet arrangement 110 for generating a pre-polarisation field in a field-of-view f and a measurement magnet arrangement 120 for generating a measurement field in the field-of-view f.

The magnet system 100 further includes a spatial encoding arrangement 130 including at least one magnetic encoding element 131 movable relative to the field-of-view f to thereby spatially encode the measurement field for each of a plurality of readings.

In particular, the magnetic encoding element 131 typically includes a permanent encoding magnet and or at least one ferromagnetic encoding element that interacts with the measurement field generated by the measurement magnet arrangement 120, thereby altering the measurement field at least in the vicinity of the encoding element. Accordingly, through suitable selection of the encoding element and movement of the encoding element relative to the field-of-view, this allows the measurement field within the field-of-view to be modified so that the measurement field is spatially encoded, thereby allowing an image of a sample in the field to be reconstructed using suitable reconstruction techniques. In particular, the encoding element ensures the measurement field is spatially encoded so that the field has different gradients at different positions. This provides a mechanism for easily generating a spatially encoded field to allow image reconstruction, without requiring the use of fields generated using electromagnetic coils, which can in turn interfere with other aspects of the field generation and measurement process.

A number of further features will now be described.

In one example, as shown in the example of FIGS. 1A to 1D, the at least one encoding element can be moved either circumferentially around the field-of-view and/or axially in a direction parallel to a field-of-view axis. In one preferred example, the at least one encoding element is moved in a spiral trajectory around and along a field-of-view axis. When moved along the axis the movement can be linear, non-linear or quadratically. It will be appreciated that different movements will result in different benefits in image reconstruction as will be described in more detail below. These different movements can be used to generate different spatially encoded measurement fields for each measurement being performed, thereby allowing resulting signals to be used in image reconstruction. Furthermore, by appropriate selection of the encoding element and movement, this can be used to optimise the image reconstruction process, as will be described in more detail below. Thus, for example, two encoding magnets could be provided that move on respective spiral paths around the field-of-view, with these paths optionally being in opposite directions, as will be described in more detail below.

In one example, the at least one magnetic encoding element is mounted on an annular support 132 extending around the field-of-view with a support axis coincident with the field-of-view axis. In this example, movement of the at least one magnetic encoding element is achieved by moving the annular support, with the movement including rotation and/or axial movement, for example to achieve a spiral path as previously described. The movement can be achieved using an actuator, such as a motor which drives the annular support along a defined path, for example in a manner similar to movement of a camera lens.

It will be appreciated that movement of the encoding element(s) can be controlled using a controller, such as one or more electronic processing devices, allowing movement of the encoding element to be synchronised with measurements being performed. This typically includes moving the magnetic encoding element(s) between successive measurements, synchronised with deactivation of the pre-polarising field as will be described below.

In one example, the magnetic encoding element includes first and second magnetic encoding elements. These can be moved collectively, for example by mounting these on a common support, although this is not essential and alternatively these can be moved independently. The magnetic encoding elements could be of the same of different sizes and could have the same or different remanent magnetisations, depending on the preferred implementation, depending on the preferred implementation.

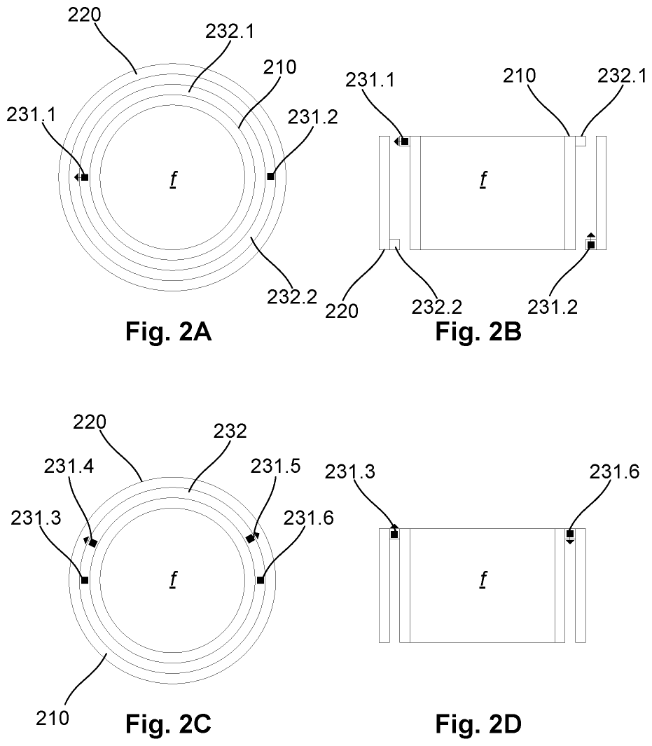

In the example shown in FIGS. 2A and 2B, two encoding elements 231.1, 231.2 are provided on respective supports 232.1, 232.2, allowing these to be moved independently, for example allowing one to be moved and/or static, whilst the other encoding element is moved relative to the measurement field. For the purpose of this example, the encoding elements 231.1, 231.2 are permanent magnets having a magnetisation direction shown by the arrows, so the encoding element 231.1 is magnetised in a perpendicular direction to an axis of the field-of-view f, whilst the encoding element 231.2 is magnetised in parallel to the field-of-view axis. However, this is not essential and it will be appreciated that other orientations could be used, so that for example both magnets could be orientated perpendicularly. Similarly, different movements can result in different spatial encoding patterns, which can assist in reconstructing an image from echo signals from a sample in the field-of-view f Again, pre-polarisation and measurement arrangements 210, 220 are shown.

In another example, as shown in FIGS. 2C and 2D, the spatial encoding arrangement can include an array including a plurality of permanent encoding magnets 231.3, 231.4, 231.5, 231.6. In this example, the plurality of permanent encoding magnets 231.3, 231.4, 231.5, 231.6 are circumferentially spaced about the field-of-view and it will be noted that in this example, the encoding magnets are generally arranged in two pairs 231.3, 231.4; 231.5, 231.6, with the encoding magnets in each pair being in relatively close proximity.

In this example, the encoding magnets 231.3, 231.4, 231.5, 231.6 are provided on a common support 232 and circumferentially spaced about a common axial position, but this is not essential and alternatively the magnets can be spaced axially. Similarly, different encoding magnets 231.3, 231.4, 231.5, 231.6 could be spaced radially from the field-of-view axis by different amounts, depending on the preferred implementation.

Additionally, at least two of the encoding magnets are provided in different orientations relative to a field-of-view axis and/or at different radial spacings from the field-of-view axis. The provision of magnets at different orientations and positions (either axial, radial or circumferential) can allow different spatial encoding to be achieved.

In the example of FIGS. 2C and 2D, the encoding magnets includes at least one encoding magnet orientated with a magnetisation direction extending perpendicularly to a field-of-view axis and at least one encoding magnet orientated with a magnetisation direction extending parallel with the field-of-view axis. In one particular preferred implementation, the encoding magnets are arranged in pairs 231.3, 231.4; 231.5, 231.6, with each pair including an encoding magnet orientated perpendicularly to a field-of-view axis and an encoding magnet orientated parallel with the field-of-view axis.

Thus, the encoding magnets can include a first encoding magnet 231.3 orientated with a magnetisation direction extending radially outward from the field-of-view axis, a second encoding magnet 231.4 orientated with a magnetisation direction extending radially outward from the field-of-view axis, a third encoding magnet 231.5 orientated with a magnetisation direction extending in a first axial direction parallel to the field-of-view axis and a fourth encoding magnet 231.6 orientated with a magnetisation direction extending in a second opposing axial direction parallel to the field-of-view axis.

However, in another example, only first and second encoding magnets are provided, both orientated with a magnetisation direction extending radially outward from the field-of-view axis and with the first and second encoding magnets being moved along respective spiral trajectories. As described in more detail below, the spiral trajectories can be parallel and circumferentially spaced, or could be in different rotational directions or different axial directions, depending on the preferred implementation.

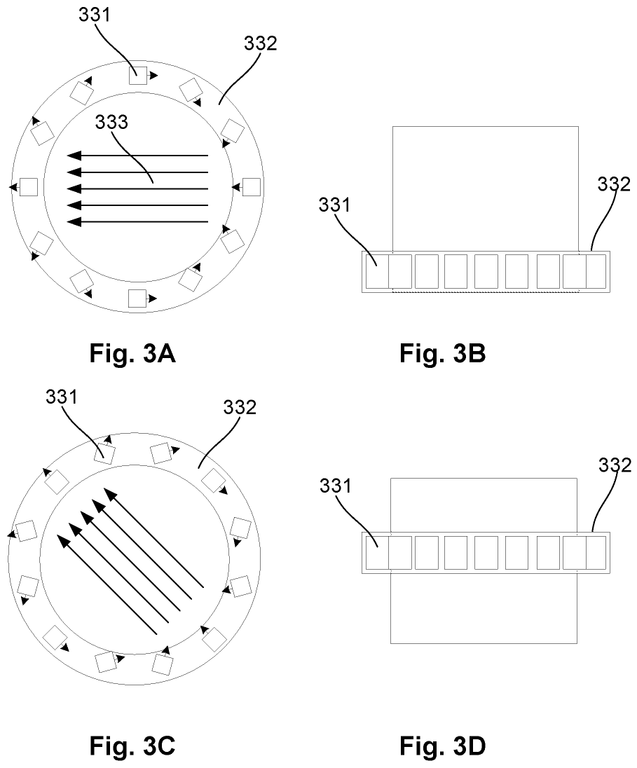

In another example, the magnetic encoding element includes an array of permanent encoding magnets that generate a predetermined spatial encoding field, which can be rotated through rotation of the encoding magnets. An example of this is shown in FIGS. 3A to 3D.

In particular, in this example, the predetermined spatial encoding field is a gradient field and the array of permanent encoding magnets including encoding magnets 331 arranged on a support 332 in a modified Halbach array, with magnets on one side of the array having a greater strength to be able to create a net gradient field shown by the arrows 333.

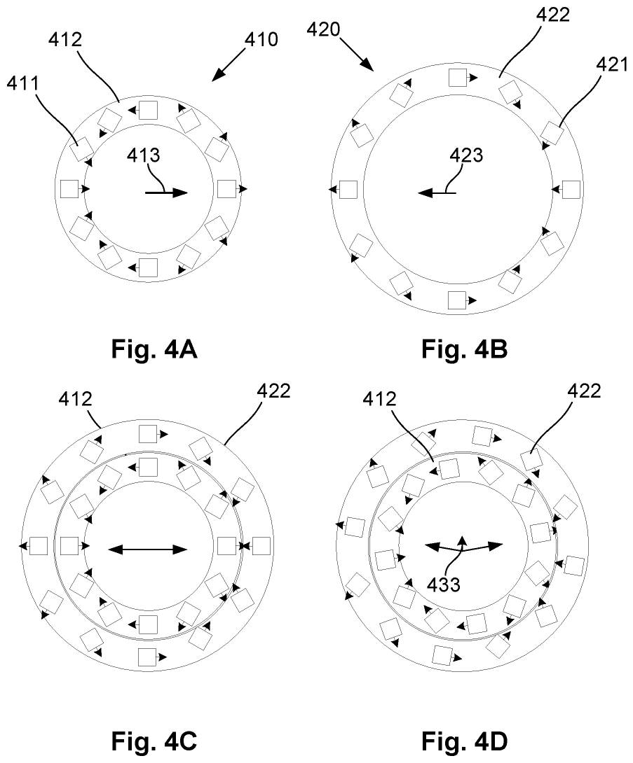

An example of a measurement magnet arrangement suitable for use in generating a measurement field for a low field magnetic resonance process will now be described with reference to FIGS. 4A to 4D. In particular, in this example measurement arrays formed from permanent magnets are provided, which can be rotated in order to generate a measurement field can be created, with positive or negative fields of different amplitudes being achieved through rotations of permanent magnet arrays.

In this example, the measurement magnet system includes a first measurement array 410, shown in FIG. 4A, which includes a plurality of permanent first measurement magnets 411 mounted in a first support 412 in a circumferentially spaced arrangement and configured to generate a first field in a field-of-view. The first field is orientated in a first direction relative to the first support, as shown by the arrow 413. The magnet system further includes a second measurement array 420 including a plurality of permanent second measurement magnets 421 mounted in a second support 422 in a circumferentially spaced arrangement and configured to generate a second field in the field-of-view, the second field being orientated in a second direction, shown by arrow 423, relative to the second support.

In use, the first and second supports are concentrically arranged about a field-of-view, as shown in FIGS. 4C and 4D, so that first and second measurement arrays can be relatively rotated allowing a strength of a measurement field in the field-of-view to be controlled.

Specifically, in the example of FIG. 4C, the first and second measurement arrays generate fields in opposition, meaning the net measurement field is minimised, and could for example have a zero field strength in the field-of-view, if the first and second measurement arrays generate fields of equal strength. In contrast to this, in the example of FIG. 4D, the first and second measurement arrays are counter rotated, with the second measurement array being rotated in a clockwise direction and the first measurement array being rotated in an anticlockwise direction, so that the first and second fields generate fields having a component extending in the direction of arrow 433, thereby generating a net measurement field extending parallel to the arrow 433.

Accordingly the above described measurement magnet arrangement can be used to generate a controllable measurement field for use in low field imaging processes. In particular, the arrangement allows a measurement to be created with a sufficiently high homogeneity to allow this to be suitable for low field imaging applications. Furthermore, the magnitude of the measurement field can be adjusted, by simply altering the relative orientation of the first and second arrays, allowing this to be achieved using physical actuation, as will be described in more detail below. This in turn makes it feasible to provide for low field measurements without requiring the use of electromagnets. This therefore significantly reduces the volume and energy requirements compared to traditional electromagnet based systems, improving portability considerably.

In particular, permanent magnets do not require electric current flow to generate magnetic fields. Hence, sample heating due to energy dissipation in a resistive material is avoided, cooling devices obviated and power consumption significantly reduced compared to resistive coil technology. Moreover, the conductivity of the material used in permanent magnets is much lower than materials like copper used in resistive coils. Hence, eddy current effects from rapid changes in magnetic field, which can lead to signal artefacts and noise, are reduced.

Accordingly, the use of the permanent measurement magnet arrangement can be used to allow low power portable imaging system to be created, which avoids significant artefacts and noise associated with electromagnetic coils, allowing an accurate portable imaging apparatus to be created which is suitable for desktop imaging applications.

A number of further features will now be described.

As mentioned above, when the first and second directions are in opposition a measurement field in the field-of-view is minimised, whereas when the first and second directions are at least partially aligned with a measurement field direction, a net measurement field is generated extending in the measurement field direction, with the strength of the measurement field being controlled by a degree of alignment of the first and second directions. To generate a null field when the fields are in opposition, it will be appreciated that the first and second fields need to have equal field strengths. However, this is not essential and alternatively non-zero minimum fields can result.

In one example, the first and second measurement arrays are configured as respective cylindrical Halbach arrays, which helps ensure the generation of homogeneous fields over the field-of-view. In this regard, Halbach arrays are a versatile arrangement of permanent magnets that can be used to generate strong, highly homogeneous magnetic fields in a field-of-view, corresponding to the field-of-view, and which are therefore well suited for use in generating the measurement fields.

In one example, the measurement magnet arrangement includes mechanical coupling between the first and second measurement arrays so that the first and second measurement arrays are rotated synchronously in opposing directions. This can be used to ensure consistency of the direction of the measurement field, whilst allowing the magnitude of the measurement field to be easily adjusted. The mechanical coupling can be of any appropriate form and could include a mechanical linkage, such as a gearing arrangement, to ensure synchronous rotation of the first and second measurement arrays.

Additionally and/or alternatively, the measurement arrangement could include a measurement actuator system for rotating the first and second permanent magnet arrays actively and relative to each other. This could include pistons coupled to the first and second supports, or could include a drive member and a mechanical linkage coupling, such as a gearing arrangement, that rotates at least one of the first and second supports. This can assist in providing electronic control of the measurement field, allowing this to be more easily controlled, although this is not essential and it will be appreciated that manual control of the measurement field could be used.

In one example, the measurement actuator system is at least one of coupled to and part of a pre-polarisation actuator system for rotating pre-polarisation magnets in a pre-polarisation measurement array between the first and second positions to thereby control a pre-polarisation field. In this instance, control of the measurement field could be performed in conjunction with control of the pre-polarisation field, for example to increase the measurement field to a desired strength as the pre-polarisation field is deactivated. However, given that the measurement field may remain constant during pre-polarisation and measurement, due to its significantly smaller magnitude than the pre-polarisation field, this is not essential.

In one example, the first and second supports include respective annular cylindrical support bodies having support body axes coincident with a field-of-view axis. The first and second supports could be of any appropriate form, but typically include two annular end plates interconnected by suitable struts, and made of a non-magnetic and substantially rigid material, such as a plastic or the like.

The measurement arrays are typically configured to generate a measurement field in a direction that is perpendicular to a pre-polarisation field direction and the field-of-view axis.

The measurement magnets are typically elongated bar magnets extending parallel to a field-of-view axis of the field-of-view and with a poles orientated perpendicularly to the field-of-view axis. The measurement magnets typically have a cross-sectional area of at least one of: at least 0.5 cm², at least 0.6 cm², less than 1.0 cm², between 0.5 cm² and 1.0 cm², between 0.6 cm² and 0.9 cm², and more typically approximately 0.72 cm². The magnets typically have a length of at least one of: at least 10 cm, at least 15 cm, less than 100 cm, less than 80 cm and more typically between 15 cm and 70 cm. The measurement magnets typically have a remanent field strength of at least one of: at least 0.1 T, at least 0.15 T and less than 0.5 T. Each measurement magnet array typically has at least one of 12 magnets, 16 magnets and 24 magnets, and a radius of at least one of less than 10 cm, more than 7.5 cm, between 8 cm and 9 cm, or at least 20 cm and less than 30 cm.

For the first and second measurement arrays to generate fields having a similar magnetic field strength, despite being arranged concentrically, it will be appreciated that the first and second measurement arrays can have different magnet configurations. For example, the first and second measurement arrays can contain different numbers of magnets, magnets with different field strengths, or both.

Typically, the resulting measurement field has at least one of: a strength adjustable between 0 μT and 10 mT, a field homogeneity of at least one of: less than 230 ppm and more typically less than 200 ppm.

In one example, the field-of-view has a volume of at least one of, at least 50 cm³, at least 75 cm³, at least 100 cm³, and more typically at least 125 cm³. It will be appreciated that the field-of-view could be of any suitable shape, such as cylindrical, spherical or the like, depending on the preferred implementation.

The measurement magnet arrangement can also be used in conjunction with a pre-polarisation magnet arrangement for generating a pre-polarisation field in the field-of-view to thereby provide a complete pre-polarisation and measurement field system. It will be appreciated if further integrated with an arrangement for providing encoding, such as a linear gradient field or non-linear encoding field, and a suitable sensing arrangement, such as a suitable magnetometer, this can be used to provide a complete imaging system.

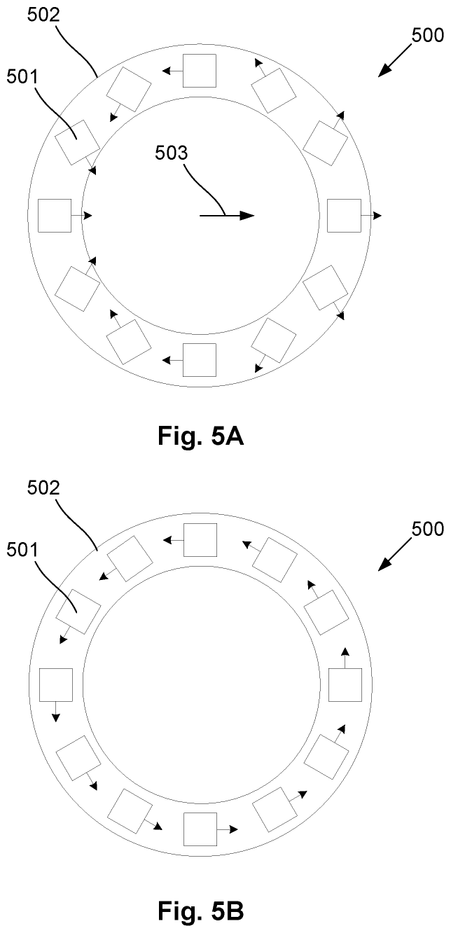

An example of a pre-polarisation magnet arrangement for generating a pre-polarisation field for use in a low field magnetic resonance process will now be described with reference to FIGS. 5A and 5B.

In this example, the pre-polarisation magnet arrangement 500 includes a pre-polarisation field array including a plurality of permanent pre-polarisation magnets 501 mounted in a support 502 and provided in a circumferentially spaced arrangement surrounding a field-of-view. Some or all of the pre-polarisation magnets 501 are movable between respective first and second positions shown in FIGS. 5A and 5B respectively.

In the first position, the pre-polarisation magnets are configured as a cylindrical Halbach array to generate a pre-polarisation field in the field-of-view, orientated as shown by the arrow 503. In this regard, Halbach arrays are a versatile arrangement of permanent magnets that can be used to generate strong, highly homogeneous magnetic fields in a field-of-view, and which are therefore well suited for use as a pre-polarisation field.

In the second position the pre-polarisation magnets are configured to minimise the pre-polarisation field in the field-of-view, and a number of different configurations of second position can be used. In the example shown in FIG. 5B, the pre-polarisation magnets are arranged tangentially, with the poles of each pre-polarisation magnet being aligned with the circumference of the array. However, this is not essential, and alternatively other configurations, such as a reverse cylindrical Halbach array or radial arrangement could be used, and relative benefits will of these different configurations will be discussed in more detail below.

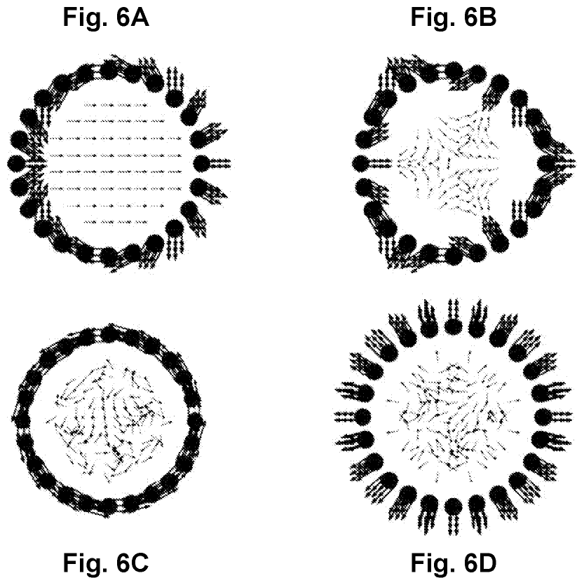

Examples of the fields produced by the Halbach array, a reverse cylindrical Halbach array, a tangential configuration and a radial configuration are shown in FIGS. 6A to 6D respectively, highlighting the strong homogeneous field for the first position and a significantly reduced field for the second position, making pre-polarisation of samples in an acquisition region feasible.

Accordingly the above described pre-polarisation magnet arrangement can be used to generate a pre-polarisation field for use in low field imaging processes. In particular, the arrangement allows a pre-polarisation field to be created with a sufficiently high homogeneity and strength to allow this to be suitable for low field imaging applications. Furthermore, the pre-polarisation field can be “turned off” effectively, by simply altering the orientation of the pre-polarisation magnets, allowing this to be achieved using physical actuation, as will be described in more detail below. This in effect provides a dynamic switchable pre-polarisation field, which in turn makes it feasible to provide for low field pre-polarisation without requiring the use of electromagnets or resistive coils. This therefore significantly reduces the volume and energy requirements compared to traditional electromagnet or coil based systems, improving portability considerably.

In particular, permanent magnets do not require electric current flow to generate magnetic fields. Hence, sample heating due to energy dissipation in resistive material is avoided, cooling devices obviated and power consumption significantly reduced compared to resistive coil technology. Moreover, the conductivity of the material used in permanent magnets is much lower than materials like copper used in resistive coils. Hence, eddy current effects from rapid changes in magnetic field, which can lead to signal artefacts and noise, are reduced.

Accordingly, the use of the permanent magnet pre-polarisation array can be used to allow lower power portable imaging system to be created, which avoids significant artefacts and noise associated with electromagnetic coils, allowing an accurate portable imaging apparatus to be created which is suitable for desktop imaging applications.

A number of further features will now be described.

Typically the pre-polarisation magnets are mounted rotatably to the support, allowing the pre-polarisation magnets to rotate about magnet axes parallel to a pre-polarisation array axis, with the direction and magnitude of the rotation depending on the particular first and second positions of each pre-polarisation magnet. It will also be appreciated that this is not essential and any rotation or other movement could be used.

In one example, wherein the pre-polarisation magnet arrangement includes a pre-polarisation actuator system for rotating the pre-polarisation magnets between the first and second positions to thereby control the pre-polarisation field. The nature of the actuator system will vary depending on the preferred implementation.

In one example, each pre-polarisation magnet is mounted in a housing, which is rotatably mounted to the support, for example using a suitable bearing or the like (not shown). The support could be of any appropriate form, but in one example has a generally annular and cylindrical form extending in an axial direction, typically made from two annular end plates interconnected by suitable struts, and made of a non-magnetic and substantially rigid material, such as a plastic or the like. The housing is used to provide a mounting that can contain the pre-polarisation magnet, allowing this to protect the pre-polarisation magnet from impact and optionally provide electrical isolation. In one example, the housing 42 is in the form of a nylon sleeve, although this is not essential and any suitable arrangement could be used. The housing can also provide a mechanism to interface with the actuator, for example, using an arm extending laterally from the sleeve.

In this example, the arm can be coupled to a piston, via a connecting arm. In this example, activation of the piston causes movement of the arm between extended and retracted positions. By suitable positioning of the pistons around the circumference of the support, this allows the pre-polarisation magnets to be rotated as required.

In such an arrangement, the pistons can be activated either pneumatically or hydraulically, avoiding the need for electrical systems, such as a motor, to be positioned near the imaging apparatus, which could in turn interfere with the magnetic fields generated by the system, including the pre-polarisation field, as well as measurement or spatial encoding fields.

To ensure accurate positioning the pre-polarisation magnets, the actuator system typically has a tolerance of less than 40 arcsecond, and is configured to move each of the pre-polarisation magnets synchronously, by a required rotational amount, to thereby deactivate the field. In this regard, it is preferable to rotate the pre-polarisation magnets between the first and second positions so that the transition is performed synchronously, meaning that as different magnets rotate by different amounts, this may require different rotation speeds. It will be appreciated that in this instance, such a movement can be coordinated by controlled delivery of fluid to the pistons.

However, it will be appreciated that alternative arrangements could be used. In one example, this could be achieved by providing a mechanical coupling between the pre-polarisation magnets so that the pre-polarisation magnets are moved in synchronisation. The mechanical coupling could be used in conjunction with a separate actuator mechanism, such as the piston arrangement described above, or alternatively could be used to act as the actuator mechanism.

Such an arrangement could include a drive member and a mechanical linkage coupling each of the number of pre-polarisation magnets and the drive, so that each of the number of pre-polarisation magnets is rotated by a defined amount in a respective direction upon actuation of the drive. For example, the drive member could include a gear wheel, with the mechanical linkage containing one or more gears, meaning that suitable selection of gearing could be used to ensure synchronous rotation of the magnets.

In this instance, movement of the pre-polarisation magnets could be effected using a rotary actuator, such as a motor, which could be a hydraulic motor, or an electric motor suitably shielded from the magnet arrangement. Alternatively, this could be performed manually.

Additionally, movement of the pre-polarisation magnets can be performed at least in part using magnetic forces between the pre-polarisation magnets. In this regard, the energy state of the pre-polarisation magnets when in the second position is generally lower than in the first position, meaning magnetic forces between the magnets can assist in rotating between the first and second positions. In this instance, the system might be primed by moving the magnets to the first position and then using a locking system to lock the pre-polarisation magnets in the first position. The locking system can be disengaged and the magnets moved to the second position once sufficient polarisation of the sample has occurred. This could be performed entirely based on the stored magnetic energy, or may be performed in conjunction with the action of an actuator, such as a piston or gear based system, and may use mechanical coupling to ensure synchronous rotation of the pre-polarisation magnets.

Whilst any configuration of permanent magnet can be used, the pre-polarisation magnets are typically elongated permanent cylindrical or rectangular bar magnets, with a remanent magnetisation orientated perpendicularly to the pre-polarisation array axis. This enables the pre-polarisation magnets to generate a homogeneous field over a sufficiently deep acquisition region extending in the axial direction.

Whilst any suitable size of permanent magnet could be used, in one example, the pre-polarisation magnets typically have a cross-sectional area of at least one of, at least 5 cm², at least 6 cm², less than 10 cm², between 5 cm² and 10 cm², between 6 cm² and 9 cm², and more typically approximately 6.8 cm² to 8 cm² The magnets typically have a length of at least one of, at least 10 cm, at least 15 cm, less than 100 cm, less than 80 cm, and, more typically between 15 cm and 70 cm, and, a remanent field strength of at least one of, at least 0.5 T, at least 0.75 T, and, more typically at least 1 T. It will be appreciated however that other arrangements of magnets and field strengths are envisaged, depending on, for example, the availability of particular permanent magnet configurations, and the ability of these to accommodate associated mechanical stresses.

The pre-polarisation magnet array can have any number of permanent magnets suitable for providing a cylindrical Halbach pre-polarisation array and examples include, but are not limited to 12, 16, or 24 magnets. The magnets are typically provided circumferentially spaced on a radius of at least 10 cm, at least 12 cm, less than 20 cm, less than 18 cm; and more typically approximately 15 cm.

As previously mentioned, the support is typically an annular cylindrical support body having a support body axis coincident with the pre-polarisation array axis, with the pre-polarisation field extending in a pre-polarisation field direction perpendicular to the pre-polarisation array axis.

With the pre-polarisation magnets in the first position, the pre-polarisation field typically has a strength in the field-of-view of at least one of, at least 10 mT, at least 50 mT and more typically at least one of, at least 100 mT and a field inhomogeneity of less than 230 ppm and more typically less than 200 ppm.

In contrast, with the pre-polarisation magnets in the second position the pre-polarisation field has a strength in the field-of-view of at least one of, less than 1 nT, less than 0.1 nT and more typically less than 0.01 nT.

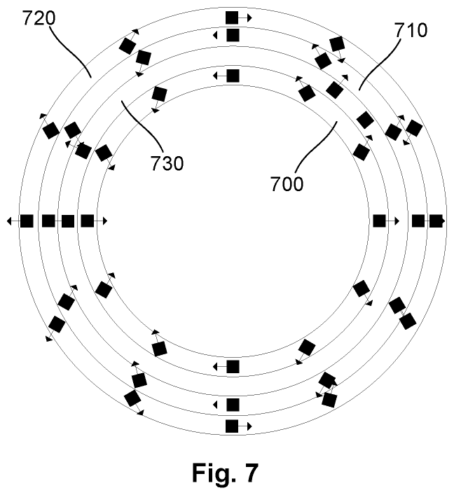

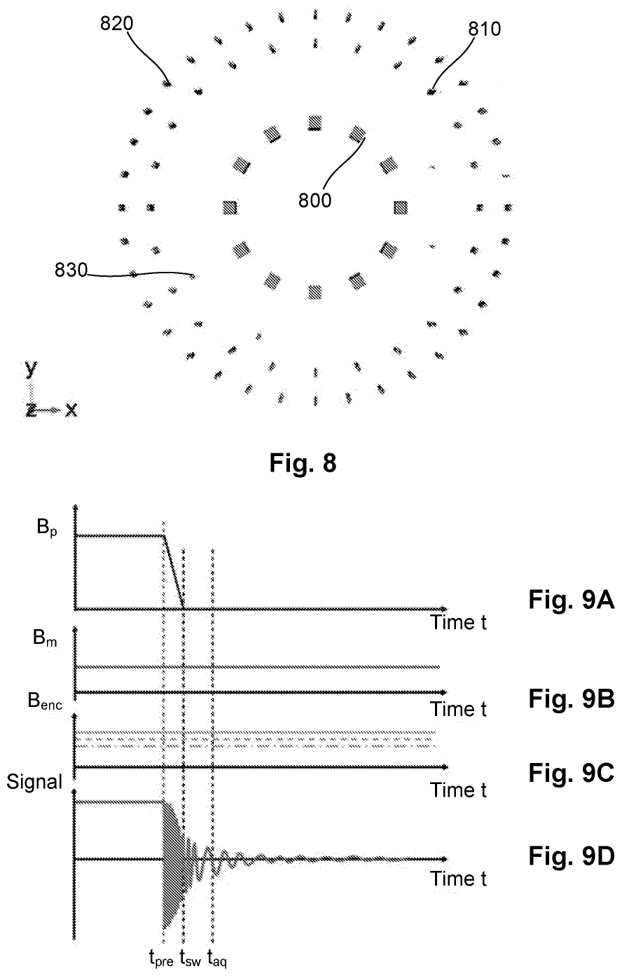

An example of a combined pre-polarisation and measurement field generating apparatus is shown in FIG. 7.

In this example, the measurement field arrays 710, 720 are positioned radially outward of the pre-polarisation field array 700, but this is for the purpose of illustration only and the pre-polarisation field array 700 could be positioned radially outward of the measurement field arrays 710, 720. Similarly, the encoding arrangement 730 could be situated at any appropriate location, including radially inward of the pre-polarisation magnet arrangement 700, radially outward of the pre-polarisation magnet arrangement 700, radially outward of the measurement magnet arrangement 710, 720 or radially inward of the measurement magnet arrangement 710, 720. In a preferred example, the encoding arrangement 730 is provided between the pre-polarisation magnet arrangement 700 and the measurement magnet arrangement 710, 720. This ensures the pre-polarisation magnets are as close to the field-of-view as possible, thereby maximising the pre-polarisation field strength, whilst the encoding magnets are next to allow maximum influence on the measurement field in the field-of-view.

The above described system can be implemented using a control system including one or more electronic processing devices that control the polarisation magnet arrangement to be able to generate a pre-polarisation field in the field-of-view to thereby polarise a sample, control a position of the at least one magnetic encoding element relative to the field-of-view to thereby control a spatial encoding of the measurement field and acquires a reading from at least one sensor with the at least one magnetic encoding element in a first position.

This process can then be repeated as required allowing multiple measurements to be performed, thereby allowing an image of a sample to be captured. It will be appreciated that typically the measurement field remains constant throughout this process, and therefore, does not need to be controlled. It will be appreciated that depending on the nature of the measurements being performed, a single measurement can be performed for each polarisation of the sample, or alternatively multiple readings could be performed for each polarisation with the processing device(s) moving the magnetic encoding element to a respective position for each of the multiple readings.

Specific example arrangements will now be described in more detail.

In this example, the dynamic permanent magnet array (PMA), includes four concentrically arranged cylindrical permanent magnet arrays 800, 810, 820, 830, including a pre-polarisation array 800 to generate the pre-polarisation field Bₚ for sample magnetisation prior to the measurement; measurement arrays 810, 820 to generate the measurement field Bₘ and setting the Larmor frequency; and encoding array 830 to generate spatial encoding fields B_{enc}, which spatially encode the measurement field allowing this to be used for image acquisition.

The pre-polarisation array 800 is located at the centre of the arrays, immediately outwardly from the field-of-view, which allows sufficiently strong pre-polarisation field Bₚ generation with fewer magnets and smaller fill factors, hence reducing mechanical stress in the system. The pre-polarisation array 800 includes 12 permanent magnets with rectangular cross sections equidistantly arranged along the circumference and individually mounted on rotating actuators. This enables pre-polarisation field Bₚ switching by rotating each of the magnets to form a Halbach array magnetisation pattern, in which the pre-polarisation field Bₚ is on and a tangential magnetisation pattern in which the pre-polarisation field Bₚ is off. Although fewer magnets generally result in increased field inhomogeneity, this is advantageous for spatial encoding with non-linear fields. Additionally, the magnetic fields generated by the magnetisation patterns are strongly confined within the pre-polarisation array 800, which significantly reduces magnetic field interference and force interaction with the other arrays outside and the regions beyond.

Each magnet is assembled from three commercially available Neodymium magnets each sized 1×1×4″, with remanent magnetisation Bᵣ=1.45 T (Allied Magnetics, Plano, US). Although other magnet cross sections are permissible, rectangular magnet blocks were chosen because of easier alignment and better mechanical properties for rotation. In this study the pre-polarisation array 800 diameter is r_{A}=0.18 m, suitable for imaging small extremities, like hands or fingers. With these parameters, the fill factor ˜0.35 and the pre-polarisation field Bₚ has a magnetic field strength of 47.95 mT.

For the purpose of illustration, the pre-polarisation field Bₚ orientation defines the x-axis of a right-handed coordinate system with the point of origin located in the measurement array centre.

The measurement array is formed from nested cylindrical Halbach arrays 810, 820 located concentrically around the pre-polarisation array 800 generate the variable measurement field Bₘ. The measurement field Bₘ is generated perpendicular to the pre-polarisation field Bₚ when the magnetic fields of the measurement arrays 810, 820 generated separately are matched in magnitude and oriented opposite to each other and simultaneously rotated about the symmetry axis of the low field NMR/MRI instrument (z-axis). The rotation angle allows for precise measurement field strength control.

It is known, however, from theoretical consideration that magnetic field strength match cannot be achieved with two Halbach arrays having different radii but the same magnet number and size. Hence, for measurement array 810 the radius and magnet parameters was set by design considerations to be r_{B}=0.35 m, with 24 magnets evenly distributed along the circumferences. The size parameters and magnet number for measurement array 820 were numerically determined. The number of possible design variables considered here were limited to array radius and number of magnets only. Also, each magnet was assumed to be assembled by two commercial readily available ferrite magnet (12×6×150 mm with remanent magnetisation Bᵣ=0.2 T, AMF magnets).

The arrangement was configured to provide a measurement field Bₘ=200 μT, equivalent to a Larmor frequency of around 8500 Hz. This is close to the range of an air-borne based magnetometer recently developed for low field NMR/MRI, with sensitivities equivalent to a superconductor quantum interference device (SQUID), but without the necessity of shielded environments and cryogenics. Sufficient field matching was achieved with the outer measurement array 820 radius set to r_{C}=0.4105 m and 36 magnets evenly distributed along the circumference.

The encoding array 830 was defined by small permanent magnets (encoding magnets) that generate spatial encoding magnetic fields controlled by prescribed individual changes of their position. In one example, the magnets are small ferrite magnets having dimensions of 25 mm×11 mm×6 mm, and a remanent magnetisation Bᵣ=0.2 T, although it will be appreciated that other arrangements could be used.

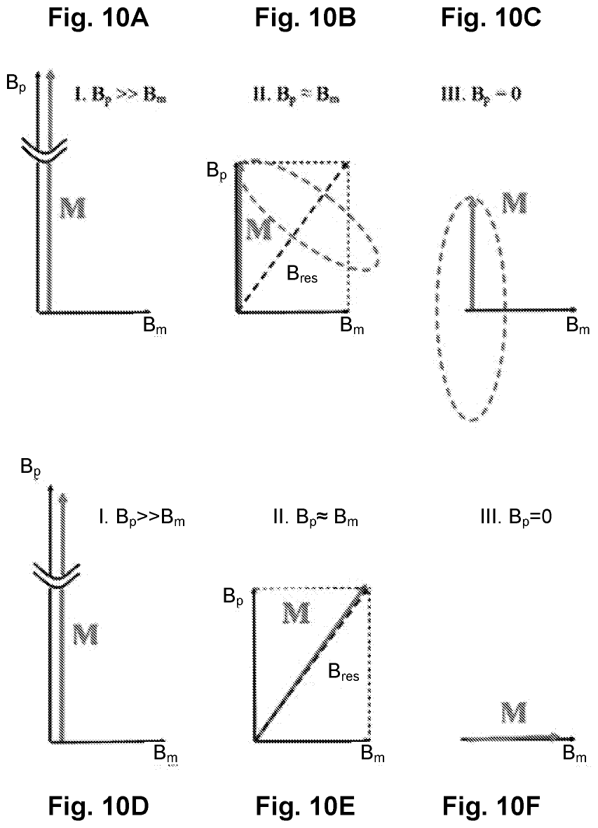

In NMR/MRI precessing magnetisation vectors M induce a measurable signal S(t) in a receiver coil after applying radio frequency (RF) pulses. However, RF pulses are not strictly necessary in low field NMR/MRI instrumentation, since signal triggering can be achieved by switching between the mutually perpendicular pre-polarisation field Bₚ and the measurement field Bₘ as shown in FIGS. 9A to 9D and 10A to 10F, which show the resulting fields for different switching conditions.

As shown in FIGS. 9A to 9D, the pre-polarisation field Bₚ is switched off at t=tₚᵣₑ (tₚᵣₑ>5·T1, T1=sample longitudinal relaxation time) by prescribed individual magnet rotation of pre-polarisation array 800.

If the pre-polarisation field Bₚ is switched off rapidly or non-adiabatically (|dBₚ/dt|>>γ²Bₘ) as shown in FIGS. 10A to 10C the magnetisation vector M will retain its original orientation and precess about a resultant magnetic field Bᵣₑₛ, by the pre-polarisation field Bₚ and measurement field Bₘ.

If the pre-polarisation field Bₚ is removed slowly or adiabatically (|dBₚ/dt|<<γ²Bₘ) as shown in FIGS. 10D to 10F the magnetisation vector M follows the resultant field Bᵣₑₛ and will be parallel to the measurement field Bₘ after the pre-polarisation field Bₚ is switched off, as shown in FIG. 10F. Hence, no precession occurs and additional RF pulses have to be applied to flip M away from Bₘ to trigger signals.

In the following specific example, simulating the signal generation process is simplified by assuming the measurement field Bₘ and the encoding field B_{enc} remain constant during one measurement (t>t_{R}, FIGS. 9A to 9D). This is because the magnitude of the measurement field Bₘ is at least three orders of magnitude lower compared to the pre-polarisation field Bₚ and will not affect the pre-polarisation field greatly. Also, the encoding field B_{enc} will be varied by rearranging the encoding magnets only during pre-polarisation. This will avoid signal artefacts, caused by the magnet and/or array motions and structural vibrations. The temporal evolution of the magnetisation vector M is described by Bloch's equation and the signal induced in a single coil by Faraday's law, respectively. Signal dephasing and decaying are characterised by the relaxation times T1 and T2, without spin-to-spin interactions considered for the signal simulation, at each sample point the Larmor frequency depends on the local magnetic field distribution only.

The generally non-linear magnetic fields produced by the measurement field Bₘ and encoding field B_{enc} precludes standard image reconstruction methods used in conventional MRI, like fast Fourier transform (FFT). This is because of non-equidistant data acquisition points (i.e. k-space is non-uniformly filled) which may result, if not corrected, in distortions and inhomogeneous resolution across the image. Instead, a back projection based image reconstruction method is implemented using the following relation

signal(t)=E(r,t)·sample(r). (1)

In this representation, the unknown sample data and the measured signal is related by the encoding matrix E. Each matrix element Eᵢⱼ describes the local time-dependent phase accumulation of the precessing magnetisation vectors, which depend on the local magnetic field strength.

In a simple experiment a signal is acquired once at time to with different encoding fields, generated by a prescribed spatial arrangement of small permanent encoding magnets:

$${S}^{( 1 )} ( {t}_{a} ) = {m}_{1} {e}^{- i {ω}_{1}^{( 1 )} {t}_{a}} + {m}_{2} {e}^{- i {ω}_{2}^{( 1 )} {t}_{a}} + … = {\sum }_{q = 1}^{{n}^{3}} {m}_{q} {e}^{- i {ω}_{q}^{( 1 )} {t}_{a}} \\ {S}^{( 2 )} ( {t}_{a} ) = {m}_{1} {e}^{- i {ω}_{1}^{( 2 )} {t}_{a}} + {m}_{2} {e}^{- i {ω}_{2}^{( 2 )} {t}_{a}} + … = {\sum }_{q = 1}^{{n}^{3}} {m}_{q} {e}^{- i {ω}_{q}^{( 2 )} {t}_{a}} \\ … \\ {S}^{( p )} ( {t}_{a} ) = {m}_{1} {e}^{- i {ω}_{1}^{( p )} {t}_{a}} + {m}_{2} {e}^{- i {ω}_{2}^{( p )} {t}_{a}} + … = {\sum }_{q = 1}^{{n}^{3}} {m}_{q} {e}^{- i {ω}_{q}^{( p )} {t}_{a}} \qquad ( 2 )$$

where m^{(j)}_{q} and ω^{(j)}_{q} are the sample magnetisation and Larmor frequency for voxel q at encoding field configuration j.

Equation (2) can be recast into a matrix equation, using Bloch's equation to include the local magnetic field B^{(j)}_{q} calculated by the simulation:

$$( \begin{matrix}{S}^{( 1 )} ( {t}_{a} ) \\ {S}^{( 2 )} ( {t}_{a} ) \\ ⋮ \\ {S}^{( q )} ( {t}_{a} )\end{matrix} ) = ( \begin{matrix}{e}^{- i γ {B}_{1}^{( 1 )} {t}_{a}} & {e}^{- i γ {B}_{2}^{( 1 )} {t}_{a}} & … . & {e}^{- i γ {B}_{q}^{( 1 )} {t}_{a}} \\ {e}^{- i γ {B}_{1}^{( 2 )} {t}_{a}} & {e}^{- i γ {B}_{2}^{( 2 )} {t}_{a}} & … . & {e}^{- i γ {B}_{q}^{( 2 )} {t}_{a}} \\ ⋮ & ⋮ & … . & ⋮ \\ {e}^{- i γ {B}_{1}^{( q )} {t}_{a}} & {e}^{- i γ {B}_{2}^{( q )} {t}_{a}} & … . & {e}^{- i γ {B}_{q}^{( q )} {t}_{a}}\end{matrix} ) ( \begin{matrix}{m}_{1} \\ {m}_{2} \\ ⋮ \\ {m}_{q}\end{matrix} ) ≡ {E}_{enc} \cdot m \qquad ( 3 )$$

In the low and low field NMR/MRI regime susceptibility artefacts or any other sample—magnetic field interactions are negligible. Hence, the encoding matrix elements Eᵢⱼ depend only on the local magnetic fields, including the encoding and measurement fields B_{enc}, Bₘ and possible external fields, and the acquisition time. For a single time acquisition per encoding field configuration, n³ different encoding magnet configurations are required, which is time consuming.

In another approach, the encoding matrix is populated by a combination of physically different encoding field configurations and with nₜₒₜ signals acquired at an interval Δt_{aq}=100 μs. The short time intervals are chosen as only small signal acquisition time windows will be available due to short tissue T1 and T2 relaxation times at low field (<100 ms), weak signal amplitude, spin decoherence and other T2* effects caused by the non-linear encoding fields. Per encoding field configuration nₜₒₜ=8 acquisitions are considered, hence the matrix size is j·nₜₒₜ=n³, the total voxel number.

Inverting the encoding matrix E_{enc} is the most straightforward method to retrieve the image information from equation (3). However, matrix inversion using standard methods such as Gauss-Jordan elimination or LU decomposition can be problematic for large matrix sizes generated by, for instance, high resolution acquisitions or using multiple receiver coils.

Another iteration based method, applied here, is based on minimising N in the rearranged image equation 1 with the Karczmarz method.

N≡∥E_{enc}·m−S∥. (4)

With this method, at the iteration step I an image m^{I} is calculated by:

$${m}_{j}^{I} = {m}_{j}^{I - 1} + \frac{{S}_{i} - {\sum }_{j} {E}_{ij}^{*} {m}_{j}^{I - 1}}{{\sum }_{j} {E}_{ij} {E}_{ij}^{*}} {E}_{ij}^{*} \qquad ( 5 )$$

From an image m^{I-1} (j=1:n³) from the previous iteration step I-1. E*ᵢⱼ is the complex conjugate of the encoding matrix elements Eᵢⱼ.

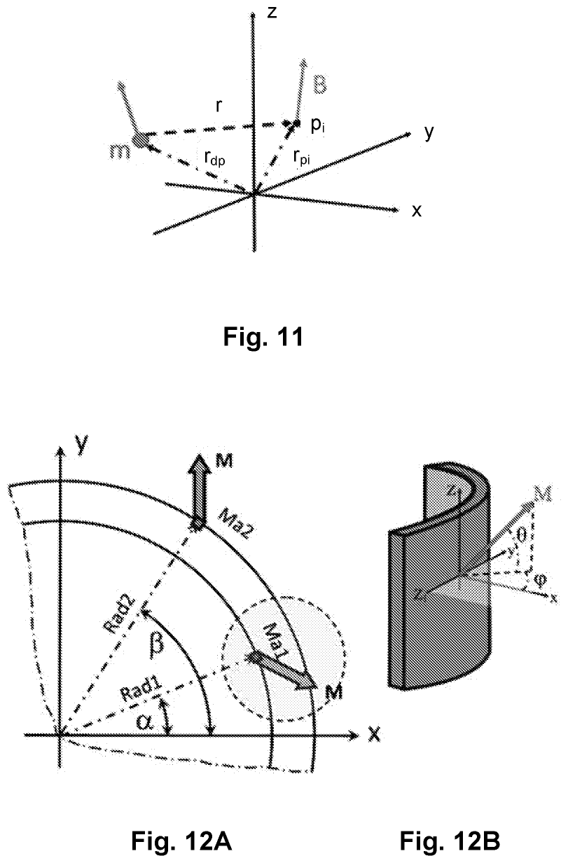

The magnetic field distribution generated by n encoding magnets with arbitrary orientation and location can be calculated analytically. FIG. 11 shows the parameters for one encoding magnet approximated by a single magnetic dipole with magnetisation m, located at r_{dp}. Assuming far-field regime or negligible magnet sizes compared with the distances r to the sample points pᵢ, B(r) is calculated in Cartesian coordinates by:

$$\begin{matrix}{B}_{x} ( {r}_{dp} , m , {r}_{pi} ) = \frac{{μ}_{0}}{4 π} \frac{3 u ( {x}_{pi} - {x}_{dp} ) - {wm}_{x}}{v} ; {B}_{y} ( {r}_{dp} , m , {r}_{pi} ) \\ = \frac{{μ}_{0}}{4 π} \frac{3 u ( {y}_{pi} - {y}_{dp} ) - {wm}_{y}}{v}\end{matrix} ; \\ {B}_{z} ( {r}_{dp} , m , {r}_{pi} ) = \frac{{μ}_{0}}{4 π} \frac{3 u ( {z}_{pi} - {z}_{dp} ) - {wm}_{z}}{v} \\ u = {m}_{x} ( {x}_{pi} - {x}_{dp} ) + {m}_{y} ( {y}_{pi} - {y}_{dp} ) + {m}_{z} ( {z}_{pi} - {z}_{dp} ) \\ v = {( {( {x}_{pi} - {x}_{dp} )}^{2} + {( {y}_{pi} - {y}_{dp} )}^{2} + {( {z}_{pi} - {z}_{dp} )}^{2} )}^{\frac{5}{2}} \\ w = {( {x}_{pi} - {x}_{dp} )}^{2} + {( {y}_{pi} - {y}_{dp} )}^{2} + {( {z}_{pi} - {z}_{dp} )}^{2}$$

At each point (encoding step number j) along a prescribed path the resultant field Bₜₒₜ generated by n encoding magnets is:

$${B}_{tot} ( {r}_{pi} ) = {\sum }_{k = 1}^{n} {B}^{k} ( {r}_{dp}^{k} , {m}^{k} , {r}_{pi}^{k} ) \qquad ( 6 )$$

After substituting resultant field Bₜₒₜ into equation (3), the encoding matrix can be evaluated using standardly available simulation packages. The rank is an estimation of the number of linearly independent rows, or equivalently independent encoding field configurations, and is aimed to be maximised. The condition number η is a measure of the accuracy of any matrix solvers, with its magnitude describing whether a problem (e.g. matrix data) is ill-conditioned (high condition number) or well-conditioned (low condition number).

Equation (3) could be subject to a generalised optimisation process to determine the associated optimal magnet numbers, their locations and orientations. However, this is time consuming since this has to be repeated for each encoding step considering appropriate constrains to ensure practical outcomes. Moreover, the theoretical one or even multiple optimal magnetic field configuration are a priori not known due to the complex geometric structure. Hence, another optimisation method based on equation (6) can be adopted as a practical approach. This involves prescribing magnet paths and orientations with respect to constrains set by the real design of the low field NMR/MRI instrument. The magnetic field distribution within the field-of-view is calculated at each encoding step, or one location along the prescribed path for each acquisition time and filled as one row into the encoding matrix. After completion, the encoding matrix is evaluated and its rank and condition number implemented as input variables for a symbolic objective function G:

G=min{f(1/ζ,η)}.

Each encoding magnet is assumed to be attached with fixed orientations (φ₁, φ₂, θ₁, θ₂) to a cylindrical support of encoding array 830 and moves about the surface in spiralling paths, generated by simultaneous array rotation and motion along the z-axis, similar to the motion of a camera zoom lens.

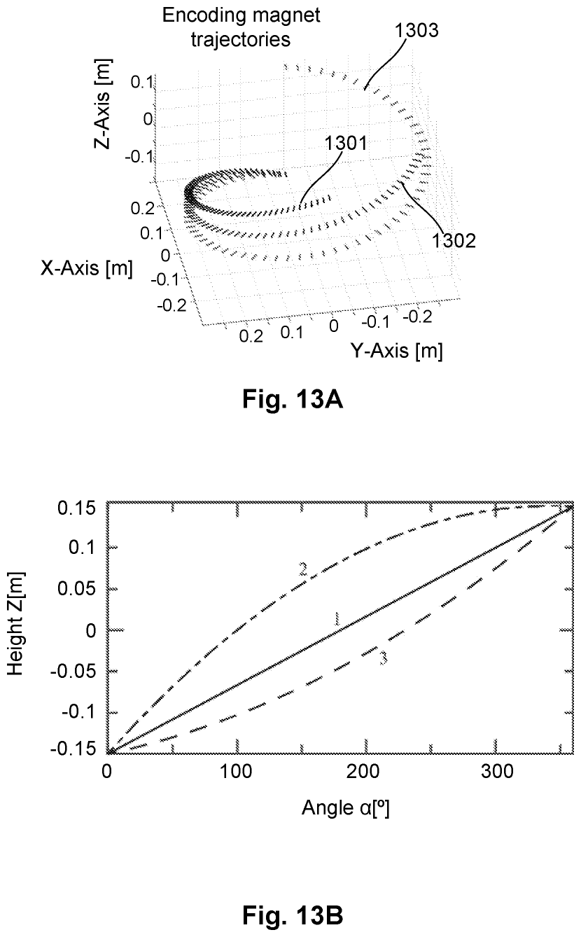

In this example first and second encoding magnets Ma₁ and Ma₂ are attached on two separate concentric cylinders with radius rad₁=0.265 m and rad₂=0.300 m, as shown in the xy-plane cross section view in FIG. 12A. The rotation angle is labelled a for the first encoding magnet Ma₁ and β for the second encoding magnet Ma₂, each with respect to the x-axis. The magnetisation direction is defined by the polar angle θ (−π to π) with respect to the xy-plane, and the azimuthal angle φ (0 to 2π) with respect to the radius vector Rad, as shown in FIG. 12B. The spiral path of the first encoding magnet Ma₁ is shown in FIGS. 13A and 13B, and is described by x_{Ma1}=Rad₁·cos (α), y_{Ma1}=Rad₁·sin (α), and the height Z (α) is defined by the following equation

Z(α)=Aα²+Bα+C. (7)

The coefficients A, B and C characterise a linear or quadratic height variation Z and are determined by

$$[ \begin{matrix}A \\ B \\ C\end{matrix} ] = {( \begin{matrix}{α}_{1}^{2} & {α}_{1} & 1 \\ {α}_{2}^{2} & {α}_{2} & 1 \\ {α}_{3}^{2} & {α}_{3} & 1\end{matrix} )}^{- 1} [ \begin{matrix}Z ( {α}_{1} ) \\ Z ( {α}_{2} ) \\ Z ( {α}_{3} )\end{matrix} ] , \qquad ( 8 )$$

where α₁ is the initial angle, α₃ the final angle, and α₂ the intermediate angle.

If α₂=(α₃−α₁)/2, the height varies linearly otherwise quadratically with the rotation angle α, as shown in FIG. 13B. Similarly for the second encoding magnet Ma₂, Rad₁ is replaced by Rad₂, and α by β.

FIG. 13A shows as an example three different spiral paths considered for one encoding magnet, with the magnetisation vector pointing outwards and placed perpendicular on the path. Three different path lengths are shown from the initial angle α₁=0° until the final angle α₃=180° (1301), α₃=240° (1302) and α₃=360° (1303). Each arrow shows one encoding step, at which the magnetic field distribution is calculated for each time acquisition. For all paths considered the initial height is z₁ (α₁)=−0.15 m and the final height z₂ (α₃)=0.15 m.

Numerical simulation of the dynamic transition of the pre-polarisation and the measurement field can be performed using finite element methods (FEM). In the FEM simulation, the low field NMR/MRI model can be discretised in 3D-tetrahedral meshes using predetermined and optimised mesh distributions. For additional accuracy, mesh density can be manually increased around the pre-polarisation magnets to achieve sub-millimetre spatial resolution in the centre of the array. The number of tetrahedral element ranged between 27-28 million for accurate and convergent results and to ensure aimed time frames of 12-24 hours per simulation. The cylindrically shaped computational window size (diameter 1.3 m, height 1.56 m) was set to be sufficiently large to model the SPMA (diameter 0.8 m, length 0.3 m) and to minimise numerical errors associated with insufficient mesh points. The relative permeability of the material in the magnets was set to 1.05 and for the surrounding environment (air) it was 1.

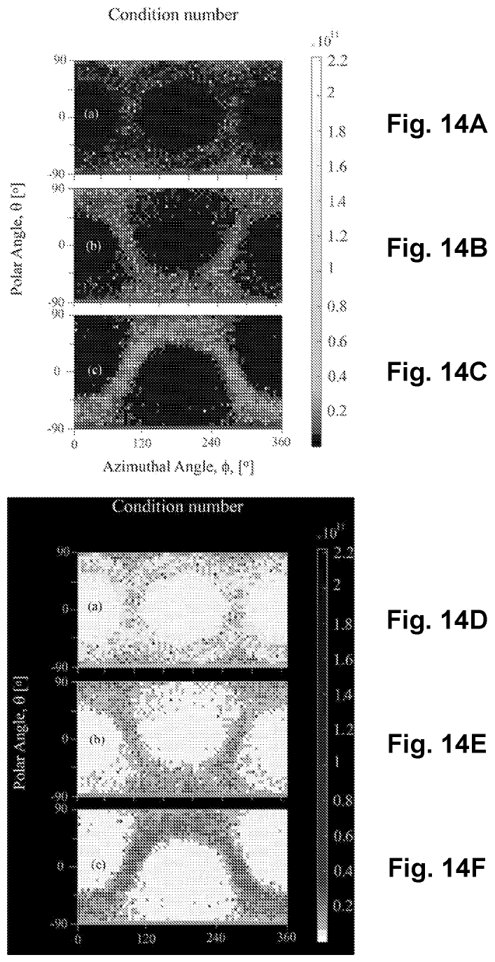

Example results of the FEM for a single encoding magnet will now be described with reference to FIGS. 14A to 14C, and the corresponding negative images in FIGS. 14D to 14F, shown for clarity.

The figures show the condition number versus the orientation angles as a grey scale surface plot for one encoding magnet Ma₁ moving along a path described in Cartesian space by T=(rad₁·cos(α), rad₁·sin(α), z(α)). The parameter a varies from the initial angle α₁=0° to the final angle α₃=360°. The intermediate angle between α₁ and α₃ varies from α₂=180° in FIG. 14A, 100° in FIG. 14B and 230° in FIG. 14C, to evaluate the effect of non-linear height variation on the condition number, as also shown in FIG. 13B.

In the grey colour scheme regions of high condition number are designated with bright colours, and low condition number by dark colours. In all cases, two broad dark regions with low condition numbers are present. For linear height variation, as shown in FIG. 14A, these regions are circularly shaped and located symmetrically around the polar angle θ=0° and azimuthal angle φ=180°. For non-linear height variations, shown in FIGS. 14B and 14C, the shape of the two low condition number regions are distorted and shifted with respect to the polar angle θ. For α₂<180° and φ=0, the polar angle shifts towards negative values, for φ=180° towards positive values, whereas for α₂>180° the shift is opposite. In contrast, the azimuthal angle remains constant for all cases considered.

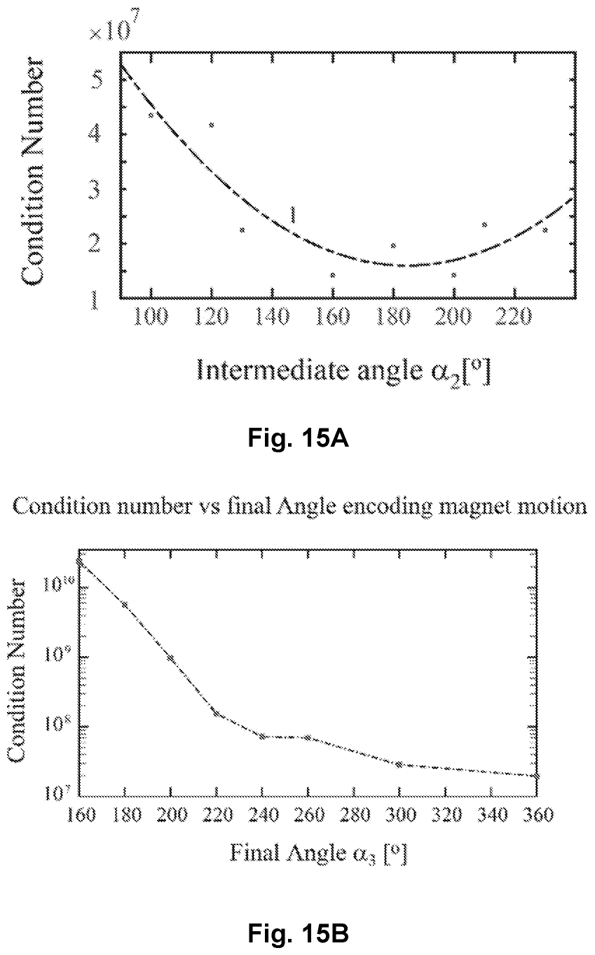

These results suggest that the optimal orientation angle for one encoding magnet is perpendicular onto the path. FIG. 15A also shows that the minimum condition number for the encoding matrix is achieved with intermediate angles near α₂=180°, or equivalently to linear height variation. Based on these results, for the remainder of this description it is assumed that the height changes linearly with rotation angle α and the magnetisation is oriented perpendicular onto the path.

The effect of shortening the spiral path by reducing the final angle α₃ to increase acquisition speed is shown in FIG. 15B. It indicates that the condition number significantly increases with reduced path length. FIG. 15B also indicates that the condition number varies by less than one order of magnitude for α₃ between 240° and 360°. This offers potentially faster spatial encoding speeds since the path length can potentially be reduced without compromising encoding efficiency.

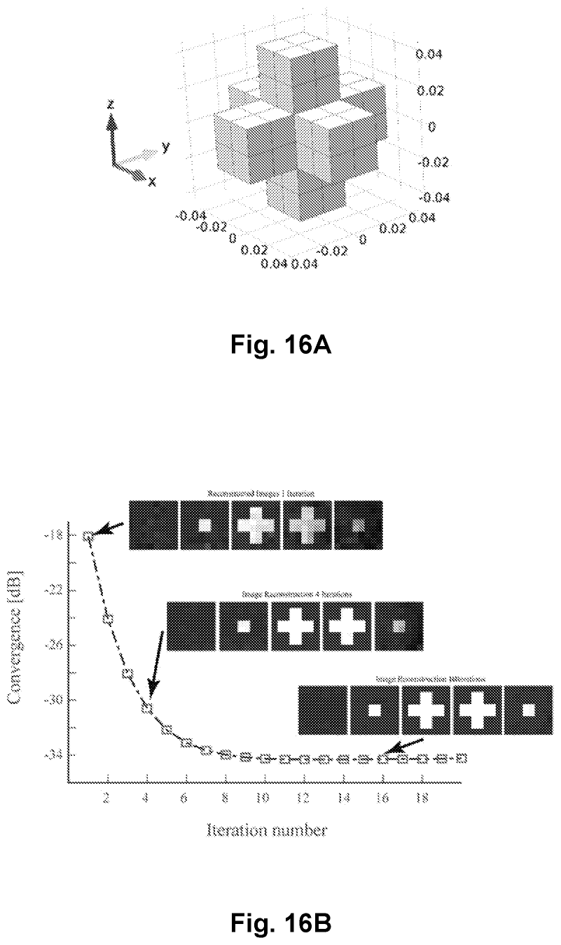

For signal generation and image reconstruction simulation a 3D cubic cross shaped tissue sample was utilised, as shown in FIG. 16A, with the tissue being surrounded by another tissue both with typical relaxation times of T1=100 ms and T2=80 ms at low field. The spin density difference which primarily determines the signal magnitude between both media was arbitrarily chosen to be 5. The convergence of the iterative Kaczmarz method for image reconstruction is shown in FIG. 16B, for a single encoding magnet Ma₁ with α₁=0°, α₂=120° and a₃=240° (path 1302 in FIG. 13A).

Five image cross sections at z=0.06 m, 0.045 m 0.015 m, −0.015 m and −0.045 m were chosen for this illustration, which qualitatively show an image convergence within 5-8 iterations. Based on this, the difference between the original and the reconstructed image is quantified by the standard deviation evaluated after the arbitrarily chosen 10 iterations.

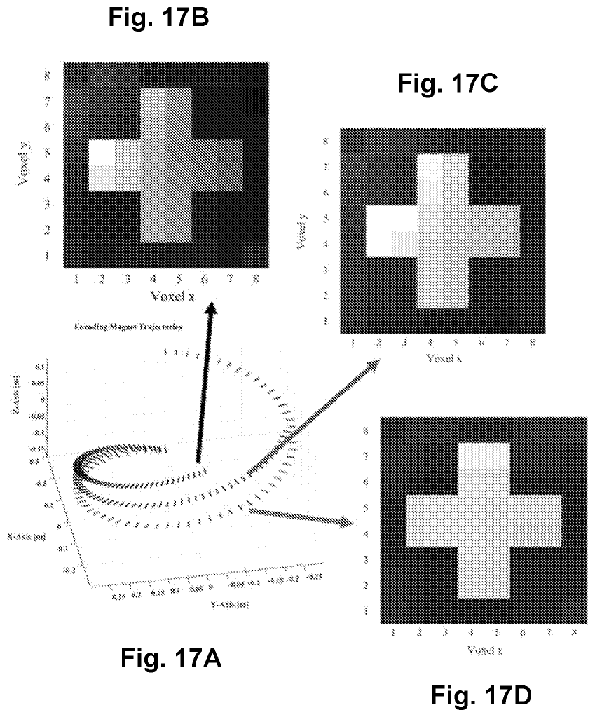

The effect of path length on image reconstruction is illustrated in FIGS. 17A to 17D, for a single cross section through centre of the sample shown in FIG. 16A. The image homogeneity and overall quality improves with increasing path length, as shown in FIG. 17D, which is also indicated by the decreasing standard deviation with increased path length, 0.0231 for α₃=180° 0.0221 for α₃=240° and 0.0200 for a₃=360°, calculated after 10 iterations. This is expected as the magnetic field generated by the single encoding magnet drops off at a rate one over distance cubed. Hence, the magnetic field interacts more strongly with the sample facing the encoding magnet, but much less otherwise. If the path length is reduced, the Larmor frequency is insufficiently modulated around the sample. This is highlighted in FIGS. 17A to 17D, where signal intensity for is unevenly distributed for α₃=180° and α₃=240°.

The previous discussion highlights that for one spatial encoding magnet with spiralling paths and linear pitch, the image quality improves with path length. However, encoding field variability with one magnet only is limited due to the one over distance cubed dependence of the magnetic field. As switching can be performed during pre-polarisation, enhanced path lengths may also result in longer encoding switch time.

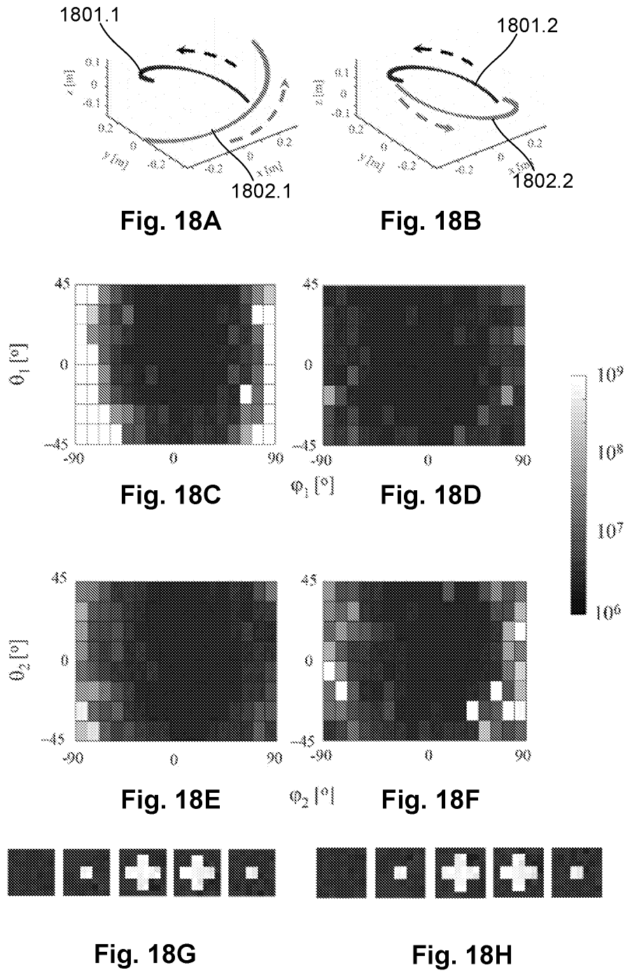

Accordingly, spatial encoding and image reconstruction with two encoding magnets is illustrated with respect to FIGS. 18A to 18H.

Two possible configurations are considered with combined path length about the circumference of the encoding array 830 to avoid biased Larmor frequency modulation and inhomogeneous sample signal generation. In both modalities magnet Ma₁ moves counter clockwise from the bottom to the top, as shown by paths 1801.1, 1801.2 in FIGS. 18A and 18B. In the first configuration of FIG. 18A, the second encoding magnet Ma₂ moves counter clockwise from the bottom to the top as shown by the path 1802.1, whereas in the second configuration the second magnet Ma₂ moves from top to the bottom as shown by the path 1802.2. The starting points of each magnet are separated by 180° and maintained throughout the motion, to ensure that each of the sample faces an encoding magnet.

Four independent parameters, namely the polar and azimuthal angles of the first and second encoding magnets, Ma₁ and Ma₂, were varied to determine the minimal condition number and optimal orientation (φ₁^{opt}, φ₂^{opt}, θ₁^{opt}, θ₂^{opt}). The condition number distribution, presented in grey scale is shown for the first arrangement in FIGS. 18C and 18D and for the second arrangement in FIGS. 18E and 18F. In all cases it is apparent that the optimal orientation angles for two magnets, like for one magnet, are perpendicular on the path (φ₁^{opt} and φ₂^{opt}˜0°) and parallel to the xy-plane (θ₁^{opt} and θ₂^{opt}˜0°).

The reconstructed images for the sample of FIG. 16A using two encoding magnets are shown in FIGS. 18G and 18H, respectively. After 10 iterations the standard deviation for the first configuration is 0.0254 whilst it is 0.0287 for the second configuration. This is expected since the area spanned by the magnet paths is almost flat for the second configuration, leading to lower magnetic field strength variability especially in the centre of the sample.

Accordingly, the above described approach provides a mechanism for performing 3D spatial encoding particularly suited for use in low field NMR/MRI applications. To achieve this, perturbations in a measurement field were introduced using magnetic elements that can be moved relative to the measurement field, and in one particular example by small permanent magnet motions. This obviates the need for resistive coil technology and its disadvantages for low field NMR/MRI, like energy dissipation into heat due to high current flow, sample heating which requires cooling devices. Furthermore, undesired signal generation due to transient currents, induced in conductors by rapid switching, is reduced because the conductivity of magnet alloys is much lower compared to conductive materials like copper.

In one particular example, a set of small permanent magnets moving along a cylindrical surface on a spiralling path, suffices for 3D encoding and image reconstruction without moving the sample or the main magnetic field.

An optimisation method was applied to determine optimal magnet orientation and location using prescribed paths considering the construction design of an example low field NMR/MRI instrument using small commercially available ferrite magnets. Such magnets are less temperature sensitive compared to, for instance, neodymium magnets, which allows higher operating temperatures and generation of stable encoding fields.

In simulation, the weak remanent magnetisation of ferrite magnets Bᵣ=0.2 T, are implemented to ensure sufficiently low encoding field strength compared to the measurement field Bₘ to account for the bandwidth limitation of the magnetic field sensor. For instance, with a measurement field Bₘ aimed at 200 μT the superposition of two encoding magnets Ma₁ and Ma₂ with remanent magnetisation Bᵣ=0.2 T results in an encoding field strength ranging from 10-30 μT, corresponding to a frequency spread of 425-1280 Hz, which is within sensing bandwidth.

It will be appreciated that whilst spiralling paths along a cylindrical surface were discussed in depth, the approach can be extended to include any number of magnets with arbitrary orientation, location moving along any prescribed paths. This approach is simpler to implement since it does not require the knowledge of the optimal magnetic field configurations for each encoding step, but the absolute optimal might not be found by this method.

The optimisation process for the low field NMR/MRI instrument revealed that typically encoding magnets orientated perpendicular onto the spiral path (azimuthal angle 0° or 180°) and the cylindrical surface (polar angle 0°). This can assist in ensuring maximal encoding matrix rank and minimal condition number for most efficient image reconstruction. However, the optimisation process shows that for the encoding magnets the condition numbers varies by less than one order of magnitude in a broad region, meaning other configurations could be used. Specifically, this in conjunction with the broad condition number minimum indicates high magnet orientation tolerance, and therefore, only moderate alignment precision is required when designing and operating the encoding array.

Shortening the path length around the sample increases the condition number of the encoding matrix and reduces the image quality as indicated by the larger standard deviation. This is expected because step size, the distance between two adjacent encoding magnet positions decreases due to reduced path length but encoding step numbers and image resolution remain unchanged. Hence, the magnetic field variation between two adjacent encoding steps is smaller and leads to an increased linear dependence between them and, subsequently, increased condition number. Moreover, due to the dipole field characteristic of small magnets, the field intensity decreases by one over distance cubed. Therefore, the magnetic field variation or Larmor frequency spread at the far side of the sample is much smaller than around the near side, thereby producing inhomogeneous lower resolution images.

Throughout this specification and claims which follow, unless the context requires otherwise, the word “comprise”, and variations such as “comprises” or “comprising”, will be understood to imply the inclusion of a stated integer or group of integers or steps but not the exclusion of any other integer or group of integers. As used herein and unless otherwise stated, the term “approximately” means±20%.

Persons skilled in the art will appreciate that numerous variations and modifications will become apparent. All such variations and modifications which become apparent to persons skilled in the art, should be considered to fall within the spirit and scope that the invention broadly appearing before described.

1) A spatial encoding arrangement forming part of a low field magnetic resonance imaging system for generating a spatially encoded measurement field for use in a low field magnetic resonance imaging process, the low field magnetic resonance imaging system including a pre-polarisation magnet arrangement for generating a pre-polarisation field in a field-of-view and a measurement magnet arrangement for generating a measurement field in the field-of-view, the spatial encoding arrangement including at least one magnetic encoding element movable relative to the field-of-view to thereby spatially encode the measurement field for each of a plurality of readings.

2) A spatial encoding arrangement according to claim 1, wherein the at least one magnetic encoding element at least one of:
a) includes at least one of:
i) flat least one permanent encoding magnet; and,
ii) at least one ferromagnetic encoding element;
b) is moved at least one of:
i) circumferentially around the field-of-view;
ii) axially in a direction parallel to a field-of-view axis;
iii) along a spiral trajectory around and along a field-of-view axis; and,
iv) axially at least one of:
(1) linearly;
(2) non-linearly; and,
(3) quadratically; and,
c) is mounted on an annular support extending around the field-of-view with a support axis coincident with the field-of-view axis.

3) (canceled)

4) (canceled)

5) (canceled)

6) A spatial encoding arrangement according to claim 1, wherein at least one of:
a) the spatial encoding arrangement includes an actuator for moving at least one magnetic encoding element; and
b) the apparatus includes one or more electronic processing devices that cause the at least one magnetic encoding element to move between successive measurements.

7) (canceled)

8) A spatial encoding arrangement according to claim 1, wherein the at least one magnetic encoding element includes first and second magnetic encoding elements and wherein:
a) the first magnetic encoding element is at least one of static and movable relative to the measurement field; and,
b) the second magnetic encoding element is movable relative to the measurement field.

9) A spatial encoding arrangement according to claim 1, wherein the at least one magnetic encoding element includes an array including a plurality of permanent encoding magnets.

10) A spatial encoding arrangement according to claim 9, wherein at least one of:
a) the plurality of permanent encoding magnets are circumferentially spaced about the field-of-view;
b) the encoding magnets are at least one of:
i) circumferentially spaced about a common axial position; and,
ii) axially spaced; and,
c) the plurality of encoding magnets includes at least two permanent encoding magnets having at least one of:
i) different orientations relative to a field-of-view axis; and,
ii) different radial spacings from the field-of-view axis.

11) (canceled)

12) (canceled)

13) A spatial encoding arrangement according to claim 10, wherein the plurality of encoding magnets includes at least one of:
a) at least one encoding magnet orientated with a magnetisation direction extending perpendicularly to a field-of-view axis; and,
b) at least one encoding magnet orientated with a magnetisation direction extending parallel with the field-of-view axis.

14) A spatial encoding arrangement according to claim 9, wherein at least one of:
a) the plurality of encoding magnets includes:
i) a first encoding magnet orientated with a magnetisation direction extending radially outwardly from the field-of-view axis; and,
ii) a second encoding magnet orientated with a magnetisation direction extending radially outwardly from the field-of-view axis, and wherein the first and second encoding magnets are moved along respective spiral trajectories and,
b) the plurality of encoding magnets includes two encoding magnets having a first radial spacing from a field-of-view axis and two encoding magnets having a second radial spacing.

15) (canceled)

16) A spatial encoding arrangement according to claim 1, wherein the at least one magnetic encoding element includes an array of permanent encoding magnets that generate a predetermined spatial encoding field.

17) A spatial encoding arrangement according to claim 16, wherein the predetermined spatial encoding field is a gradient field and the array of permanent encoding magnets is a modified Halbach array.

18) A spatial encoding arrangement according to claim 1, wherein the spatial encoding arrangement includes:
a) at least one magnetic encoding element mounted to a first support; and,
b) at least one magnetic encoding element mounted to a second support, at least one of the first and second supports being movable relative to the measurement encoding magnet arrangement.

19) A magnet system for use in a low field magnetic resonance imaging process, the system including:
a) a pre-polarisation magnet arrangement for generating a pre-polarisation field in a field-of-view;
b) a measurement magnet arrangement for generating a measurement field in the field-of-view;
c) a spatial encoding arrangement including at least one magnetic encoding element movable relative to the field-of-view to thereby spatially encode the measurement field for each of a plurality of readings.

20) (canceled)

21) A magnet system according to claim 19, wherein the at least one magnetic encoding element is provided at least one of:
a) radially inwardly of the pre-polarisation magnet arrangement;
b) radially outwardly of the pre-polarisation magnet arrangement;
c) radially outwardly of the measurement magnet arrangement;
d) radially inwardly of the measurement magnet arrangement; and,
e) between the pre-polarisation magnet arrangement and the measurement magnet arrangement.

22) A magnet system according to claim 19, wherein:
a) the pre-polarisation magnet arrangement generates a pre-polarisation field having a pre-polarisation field direction perpendicular to the array axis; and,
b) the measurement magnet arrangement generates a measurement field having a measurement field direction perpendicular to the array axis and the pre-polarisation field direction.

23) A magnet system according to claim 19, wherein the measurement magnet arrangement includes:
a) a first measurement array including a plurality of permanent first measurement magnets mounted in a first support in a circumferentially spaced arrangement and configured to generate a first field in a field-of-view, the first field being orientated in a first direction relative to the first support; and
b) a second measurement array including a plurality of permanent second measurement magnets mounted in a second support in a circumferentially spaced arrangement and configured to generate a second field in the field-of-view, the second field being orientated in a second direction relative to the second support, wherein the first and second supports are concentrically arranged about a field-of-view so that first and second measurement arrays can be rotated relatively allowing a strength of a measurement field in the field-of-view to be controlled.

24) A magnet system according to claim 23, wherein:
a) when the first and second directions are in opposition a measurement field in the field-of-view is minimised; and,
b) when the first and second directions are at least partially aligned with a measurement field direction, a net measurement field is generated extending in the measurement field direction, with the strength of the measurement field being controlled by a degree of alignment of the first and second directions.

25) A magnet system according to claim 23, wherein the first and second measurement arrays are configured as respective cylindrical Halbach arrays.

26) (canceled)

27) (canceled)

28) (canceled)

29) (canceled)

30) (canceled)

31) (canceled)

32) (canceled)

33) (canceled)

34) (canceled)

35) A magnet system according to claim 19, wherein the pre-polarising magnet arrangement including a pre-polarisation field array including a plurality of permanent pre-polarisation magnets mounted in a support and provided in a circumferentially spaced arrangement surrounding the field-of-view, a number of the pre-polarisation magnets being rotatable between respective first and second positions, wherein:
a) in the first position the pre-polarisation magnets are configured as a cylindrical Halbach array to generate a pre-polarisation field in the field-of-view; and,
b) in the second position the pre-polarisation magnets are configured to minimise a field in the field-of-view.

36) A magnet system according to claim 35, wherein in the second position the pre-polarisation magnets are arranged at least one of:
a) in a reverse cylindrical Halbach array;
b) tangentially; and,
c) radially.

37) (canceled)

38) (canceled)

39) (canceled)

40) (canceled)

41) (canceled)

42) (canceled)

43) (canceled)

44) (canceled)

45) (canceled)

46) (canceled)

47) (canceled)

48) (canceled)

49) (canceled)

50) (canceled)

51) (canceled)

52) (canceled)

53) (canceled)

54) (canceled)

55) (canceled)
